(19) United States
(12) Patent Application Publication
(10) Pub. No.: US 2011/0214736 A1
(43) Pub. Date: Sep. 8, 2011

(54) PHOTODIODE, IMAGE SENSOR AND SOLAR CELL

(76) Inventors: Tae-Yon LEE, Seoul (KR); Dong-Seok Suh, Hwaseong-si (KR)

(21) Appl. No.: 13/010,373

(22) Filed: Jan. 20, 2011

(30) Foreign Application Priority Data
Mar. 5, 2010 (KR) 10-2010-0020023

(51) Int. Cl. H01L 31/032; H01L 29/18

(52) U.S. Cl. 136/258; 257/42; 257/E29.088

(57) ABSTRACT

A photodiode includes a p-type semiconductor material and an n-type chalcogenide compound. The p-type semiconductor material and the n-type chalcogenide compound form a pn-junction.

### CROSS-REFERENCE TO RELATED APPLICATION

This application claims priority under 35 U.S.C. §119 to Korean Patent Application No. 10-2010-0020023, filed on Mar. 5, 2010, the entire disclosure of which is hereby incorporated by reference herein in its entirety.

### BACKGROUND

1. Technical Field

Example embodiments relate to photodiodes, methods of manufacturing the photodiodes and photoelectric devices and more particularly to photodiodes absorbing long wavelength light, methods of manufacturing the photodiodes, and photoelectric devices, such as image sensors, solar cells, etc., including the photodiodes.

2. Description of the Related Art

Photoelectric devices, such as image sensors, solar cells, photo detectors, etc., may require to be manufactured with material having high quantum efficiency to improve the performance. For example, in a three-dimensional image sensor providing depth information, since a photosensitive region may have to sense infrared light having a wavelength longer than that of visible light, the photosensitive region may require high photo-absorption efficiency with respect to long wavelength light. In an example of a solar cell, photo-electric conversion efficiency may be reduced if a photosensitive region of the solar cell does not sufficiently absorb the long wavelength light. Accordingly, the photosensitive region of the image sensor or the solar cell may need to be manufactured with material having an energy bandgap lower than that of silicon material to sufficiently absorb the long wavelength light and to have high quantum efficiency. Thus, there is a need in the art for a photodiode formed of a material that is thermally stable, has high photo-absorption efficiency, and can be used in a photoelectric device.

### SUMMARY

Some example embodiments may provide a photodiode having high photo-absorption efficiency.

Some example embodiments may provide a method of manufacturing a photodiode having high photo-absorption efficiency.

Some example embodiments may provide an image sensor including a photodiode having high photo-absorption efficiency.

Some example embodiments may provide a solar cell including a photodiode having high photo-absorption efficiency.

According to example embodiments, a photodiode includes a p-type semiconductor material and an n-type chalcogenide compound. The p-type semiconductor material and the n-type chalcogenide compound form a pn-junction.

In some embodiments, the p-type semiconductor material may be a p-type chalcogenide compound, and the pn-junction may be a homojunction.

The p-type semiconductor material may be selected from the group consisting of XₐSb_{b}S_{1-a-b}, XₐSb_{b}Te_{1-a-b} and XₐSb_{b}Se_{1-a-b}, where 0<a<1, 0<b<1, and X is selected from the group consisting of Si, Ge, Sn, Pb, Al, Ga, In, Cu, Zn, Ag, Cd, Ti, V, Cr, Mn, Fe, Co and Ni or a combination thereof.

The p-type semiconductor material may be Ge₂Sb₂Te₅.

In other embodiments, the p-type semiconductor material may be a silicon material or a group III-V compound semiconductor material, and the pn-junction may be a heterojunction.

In some embodiments, the n-type chalcogenide compound may be obtained from a p-type chalcogenide compound by substituting bismuth (Bi) for at least part of an element included in the p-type chalcogenide compound.

In some embodiments, the n-type chalcogenide compound may be selected from the group consisting of Xₐ(Sb₁₋ₓBiₓ)_{b}S_{1-a-b}, Xₐ(Sb₁₋ₓBₓ)_{b}Te_{1-a-b} and Xₐ(Sb₁₋ₓBiₓ)_{b}Se_{1-a-b}, where 0<a<1, 0<b<1, 0<x<1, and X is selected from the group consisting of Si, Ge, Sn, Pb, Al, Ga, In, Cu, Zn, Ag, Cd, Ti, V, Cr, Mn, Fe, Co and Ni or a combination thereof.

In some embodiments, x in Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b} may be determined based on a conductivity of the n-type chalcogenide compound and a phase change according to temperature of the n-type chalcogenide compound.

In some embodiments, x in Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b} may be more than about 0.3 and less than about 0.6.

In some embodiments, the n-type chalcogenide compound may be Ge₂(Sb₁₋ₓBiₓ)₂Te₅, where 0<x<1.

In some embodiments, the n-type chalcogenide compound may be formed by a co-sputtering process using a first target including Bi and a second target including no Bi.

In some embodiments, the first target may be Ge₂Bi₂Te₅, and the second target may be Ge₂Sb₂Te₅.

In some embodiments, a ratio of an amount of Ge₂Bi₂Te₅ to an amount of Ge₂Sb₂Te₅ may be determined based on a conductivity of the n-type chalcogenide compound and a phase change according to temperature of the n-type chalcogenide compound. The amount of Ge₂Bi₂Te₅ is more than about 30 mol % and less than about 60 mol %.

In other embodiments, the n-type chalcogenide compound may be formed by forming a p-type chalcogenide compound lacking at least part of an element and by doping the p-type chalcogenide compound with Bi.

In still other embodiments, the n-type chalcogenide compound may be formed by a sputtering process using one target or by a chemical vapor deposition process.

According to example embodiments, a photodiode is provided. The photodiode includes a p-type semiconductor material and an n-type chalcogenide compound formed on an upper surface of the p-type semiconductor material to form a pn-junction structure with the p-type semiconductor material. The p-type semiconductor material is a silicon material or a group III-V compound semiconductor material. The n-type chalcogenide compound is selected from the group consisting of Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b}, where 0<a<1, 0<b<1, 0<x<1, and X is selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni) or a combination thereof and x in Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b} is more than about 0.3 and less than about 0.6.

According to example embodiments, a photodiode is provided. The photodiode includes a p-type chalcogenide compound and an n-type chalcogenide compound formed on an upper surface of the p-type chalcogenide compound to form a pn-junction structure with the p-type chalcogenide compound. The p-type chalcogenide compound is selected from the group consisting of XₐSb_{b}S_{1-a-b}, XₐSb_{b}Te_{1-a-b} and XₐSb_{b}Se_{1-a-b}, where 0<a<1, 0<b<1, and X is selected from the consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni) or a combination thereof. The n-type chalcogenide compound is selected from the group consisting of Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b}, where 0<a<1, 0<b<1, 0<x<1, and X is selected from the group consisting of Si, Ge, Sn, Pb, Al, Ga, In, Cu, Zn, Ag, Cd, Ti, V, Cr, Mn, Fe, Co and Ni or a combination thereof and x in Xₐ(Sb₁₋ₓBiₓ)_{b}S_{1-a-b}, Xₐ(Sb₁₋ₓBₓ)_{b}Te_{1-a-b} and Xₐ(Sb₁₋ₓBiₓ)_{b}Se_{1-a-b} is more than about 0.3 and less than about 0.6.

According to example embodiments, an image sensor includes a photodiode, a transfer device and a dielectric layer. The photodiode includes a p-type semiconductor material and an n-type chalcogenide compound forming a pn-junction with the p-type semiconductor material. The transfer device is configured to transfer photo-charges generated in the photodiode. The dielectric layer covers the transfer device.

In some embodiments, the n-type chalcogenide compound may be selected from the group consisting of Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b}, where 0<a<1, 0<b<1, 0<x<1, and X is selected from the group consisting of Si, Ge, Sn, Pb, Al, Ga, In, Cu, Zn, Ag, Cd, Ti, V, Cr, Mn, Fe, Co and Ni or a combination thereof.

According to example embodiments, a solar cell includes a photodiode , a lower electrode and an upper electrode. The photodiode includes a p-type semiconductor material and an n-type chalcogenide compound forming a pn-junction with the p-type semiconductor material. The lower electrode is formed on a surface of the p-type semiconductor material. The upper electrode is formed on a portion of a surface of the n-type chalcogenide compound.

In some embodiments, the n-type chalcogenide compound may be selected from the group consisting of Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b}, where 0<a<1, 0<b<1, 0<x<1, and X is selected from the group consisting of Si, Ge, Sn, Pb, Al, Ga, In, Cu, Zn, Ag, Cd, Ti, V, Cr, Mn, Fe, Co and Ni or a combination thereof.

### BRIEF DESCRIPTION OF THE DRAWINGS

Illustrative, non-limiting example embodiments will be more clearly understood from the following detailed description taken in conjunction with the accompanying drawings.

FIG. 1 is a cross-sectional view of a photodiode according to an example embodiment.

FIG. 2 is a graph illustrating X-ray diffraction patterns of Ge₂Sb₂Te₅, Ge₂(Sb₁₋ₓBiₓ)₂Te₅ and Ge₂Bi₂Te₅ at room temperature.

FIG. 3 a graph illustrating X-ray diffraction patterns of Ge₂Sb₂Te₅, Ge₂(Sb₁₋ₓBiₓ)₂Te₅and Ge₂Bi₂Te₅ heat-treated at about 200° C.

FIG. 4 a graph illustrating resistivity of Ge₂Sb₂Te₅, Ge₂(Sb₁₋ₓBiₓ)₂Te₅ and Ge₂Bi₂Te₅ according to temperature.

FIG. 5 a graph illustrating extinction coefficients and absorption coefficients of Ge₂Sb₂Te₅, Ge₂(Sb₁₋ₓBiₓ)₂Te₅ and Ge₂Bi₂Te₅ according to temperature.

FIG. 6 is a cross-sectional view of a field-effect transistor (FET) device for conductive experiments.

FIGS. 7A through 7F illustrate I-V curves of samples 11 through 16, respectively.

FIG. 8 is a cross-sectional view of an infrared image sensor according to an example embodiment.

FIG. 9 is a cross-sectional view for describing a method of manufacturing an infrared image sensor of FIG. 8.

FIG. 10 is a cross-sectional view of an infrared image sensor according to an example embodiment.

FIG. 11 is a cross-sectional view for describing a method of manufacturing an infrared image sensor of FIG. 10.

FIG. 12 is a cross-sectional view of an infrared image sensor according to an example embodiment.

FIG. 13 is a cross-sectional view for describing a method of manufacturing an infrared image sensor of FIG. 12.

FIG. 14 is a cross-sectional view of a solar cell according to an example embodiment.

FIG. 15 is a cross-sectional view for describing a method of manufacturing a solar cell of FIG. 14.

FIG. 16 is a cross-sectional view of a photodiode according to an example embodiment.

FIG. 17 is a cross-sectional view of an infrared image sensor according to an example embodiment.

FIG. 18 is a cross-sectional view for describing a method of manufacturing an infrared image sensor of FIG. 17.

FIG. 19 is a cross-sectional view of an infrared image sensor according to an example embodiment.

FIG. 20 is a cross-sectional view of an infrared image sensor according to an example embodiment.

FIG. 21 is a cross-sectional view of a solar cell according to an example embodiment.

FIG. 22 is a cross-sectional view of a solar cell according to an example embodiment.

FIG. 23 is a block diagram illustrating a computing system according to an example embodiment.

### DETAILED DESCRIPTION OF THE EXAMPLE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

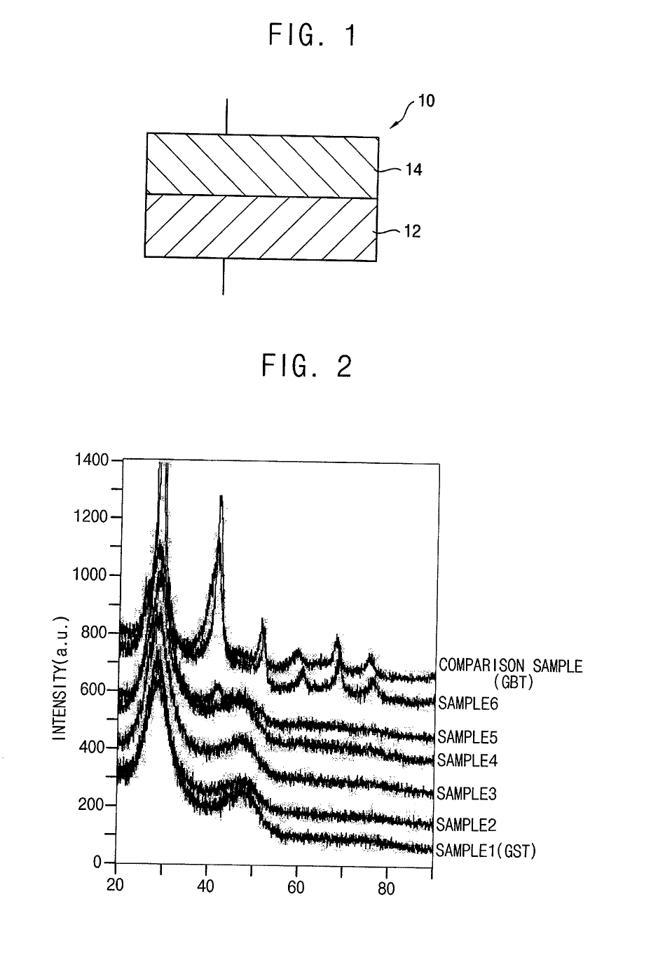

FIG. 1 is a cross-sectional view of a photodiode according to example embodiments.

A photodiode 10 is a semiconductor where photo-energy of incident light is converted into electric energy. The photodiode 10 has a junction structure of a p-type semiconductor layer and an n-type semiconductor layer. The p-type semiconductor layer and the n-type semiconductor layer form a pn-junction.

Referring to FIG. 1, the photodiode 10 may absorb visible light and infrared light having a wavelength longer than that of the visible light. Further, the photodiode 10 may have high quantum efficiency with respect to the infrared light, and may sufficiently generate photo-charges by the infrared light.

Silicon or group III-V compound semiconductor material, which is used in a typical photodiode may have high quantum efficiency with respect to the visible light. However, the silicon or the group III-V compound semiconductor material may not be used in the photodiode 10 that senses the infrared light having a wavelength longer than that of the visible light. The silicon has an energy bandgap of about 1.1 eV, and has the quantum efficiency of about 0% with respect to the infrared light. Accordingly, a photodiode made of the silicon may not almost generate the photo-charges in response to the infrared light. Further, since the silicon in the photodiode should have a thickness of several tens or hundreds μm to absorb long wavelength light, efficiency of charge transfer by diffusion of the photo-charges may be deteriorated.

The photodiode 10 according to some example embodiments can generate the photo-charges in response to the infrared light. In theory, since a cutoff wavelength is obtained by an equation of λg=hc/Eg (where λg represents the cutoff wavelength, h represents Planck's constant, c represents light velocity in vacuum, and Eg represents an energy bandgap), the lower the energy bandgap becomes, the more the long wavelength light may be absorbed. Accordingly, it is preferable that the photodiode 10 is formed of a semiconductor material having an energy bandgap lower than about 1.1 eV instead of the typically used semiconductor material. It is also preferable that the semiconductor material of the photodiode 10 has a large photo-absorption coefficient, which results in a low thickness.

A chalcogenide compound is used as the semiconductor material in the photodiode 10. For example, the chalcogenide compound may be a non-oxide glass including at least one element of sulfur (S), selenium (Se) and tellurium (Te), which are referred to as chalcogens, in group VI of the periodic table. The chalcogenide compound may further include a metal element, such as, for example, arsenic (As), antimony (Sb), thallium (Ti), etc., or a halogen element, such as iodine (I), bromine (Br), etc., to have various glass structures and various physical/chemical characteristics.

The energy bandgap of the chalcogenide compound may be lower than about 1.0 eV, and may be readily adjusted according to a combination of materials. Further, the chalcogenide compound has a large photo-absorption coefficient and high quantum efficiency. Accordingly, the chalcogenide compound is suitable for the photodiode 10.

The chalcogenide compound used for the photodiode 10 should be stoichiometrically stable such that phase separation may not occur even at high temperature. The photodiode 10 has a junction structure of a p-type chalcogenide compound 12 and an n-type chalcogenide compound 14.

Most chalcogenide compounds typically have p-type conductivity. Thus, obtaining a chalcogenide compound having n-type conductivity may be required to form the photodiode 10. Further, the p-type chalcogenide compound 12 and the n-type chalcogenide compound 14 should have similar structures and be thermally stable.

The n-type chalcogenide compound 14 according to example embodiments includes, for example, bismuth (Bi). For example, the n-type chalcogenide compound 14 may include Bi instead of at least part of an element included in the p-type chalcogenide compound 12 in the same group as Bi, or group 5B.

The p-type chalcogenide compound 12 may include, for example, XₐSb_{b}S_{1-a-b}, XₐSb_{b}Te_{1-a-b}, XₐSb_{b}Se_{1-a-b} (0<a<1, 0<b<1), etc. Here, the X includes, for example, silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co), nickel (Ni), or a combination thereof

The n-type chalcogenide compound 14 may include, for example, Xₐ(Sb₁₋ₓBiₓ)_{b}S_{1-a-b}, Xₐ(Sb₁₋ₓBiₓ)_{b}Te_{1-a-b}, Xₐ(Sb₁₋ₓBiₓ)_{b}Se_{1-a-b} (0<a<1, 0<b<1, 0<x<1), etc. The X includes, for example, Si, Ge, Sn, Pb, Al, Ga, In, Cu, Zn, Ag, Cd, Ti, V, Cr, Mn, Fe, Co, Ni, or a combination thereof.

For example, the p-type chalcogenide compound 12 may be Ge₂Sb₂Te₅, and the n-type chalcogenide compound 14 may be Ge₂(Sb₁₋ₓBiₓ)₂Te₅ (0<x<1). The n-type chalcogenide compound 14 may be obtained by, for example, substituting Bi for part of Sb included in the Ge—Sb—Te chalcogenide compound using the Bi as a dopant.

The Ge₂(Sb₁₋ₓBiₓ)₂Te₅ has more n-type conductivity as the amount of the Bi increases. For example, if x is more than about 0.1, and less than about 0.3, the Ge₂(Sb₁₋ₓBiₓ)₂Te₅ has bipolar conductivity. If, for example, x is more than about 0.3, the Ge₂(Sb₁₋ₓBiₓ)₂Te₅ has the n-type conductivity.

However, if the amount of the Bi increases, the Ge₂(Sb₁₋ₓBiₓ)₂Te₅ may have a crystalline phase. For example, if x is more than about 0.6, the Ge₂(Sb₁₋ₓBiₓ)₂Te₅ has the crystalline phase at room temperature. Since the Ge₂Sb₂Te₅ has an amorphous phase at room temperature, the Ge₂(Sb₁₋ₓBiₓ)₂Te₅ may have a phase different from that of Ge₂Sb₂Te₅ if x is more than about 0.6. Accordingly, it is preferable that x in the Ge₂(Sb₁₋ₓBiₓ)₂Te₅ is more than about 0.3 and less than about 0.6.

As described above, in the n-type chalcogenide compound 14, at least part of an element, which is in the same group as Bi, included in the p-type chalcogenide compound 12 is substituted with the Bi. Since the n-type chalcogenide compound 14 including the Bi is stoichiometrically stable, phase separation may not occur in the n-type chalcogenide compound 14. Further, since a phase change characteristic according to temperature and a photo-absorption coefficient characteristic of the n-type chalcogenide compound 14 including the Bi are similar to those of the p-type chalcogenide compound 12, the photodiode 10 having the junction structure thereof is thermally stable.

The p-type chalcogenide compound 12 and the n-type chalcogenide compound 14 included in the photodiode 10 may form a homojunction. Since the photodiode 10 is formed of the chalcogenide compounds 12 and 14 having large photo-absorption coefficients, the photodiode 10 can absorb most incident light of a long wavelength, and electron-hole pairs can be generated by the absorbed light in a junction region. Accordingly, the photodiode 10 has high quantum efficiency. Further, since the photodiode 10 may be formed thin, the generated electron-hole pairs may rapidly move without recombination, thereby reducing a signal transfer time. Accordingly, compared to a typical photodiode formed of the silicon or the group III-V compound semiconductor material, the photodiode 10 according to some example embodiments has an improved performance.

Hereinafter, a method of forming the photodiode 10 illustrated in FIG. 1 will be described.

The p-type chalcogenide compound 12 is formed on a substrate (not shown). The p-type chalcogenide compound 12 may be formed by, for example, a sputtering process. For example, a Ge₂Sb₂Te₅ layer may be formed as the p-type chalcogenide compound 12.

The n-type chalcogenide compound 14 is formed on a surface of the p-type chalcogenide compound 12. The n-type chalcogenide compound 14 includes Bi instead of at least part of the element, which is in the same group as Bi, included in the p-type chalcogenide compound 12.

In some embodiments, the n-type chalcogenide compound 12 may be formed by, for example, a co-sputtering process using two targets. In other embodiments, a p-type chalcogenide compound lacking at least part of a group 5B element may be formed, and the p-type chalcogenide compound may be doped with the Bi to form the n-type chalcogenide compound 12. In still other embodiments, the n-type chalcogenide compound 12 may be formed by, for example, a chemical vapor deposition (CVD) process.

For example, Ge₂(Sb₁₋ₓBiₓ)₂Te₅ may be formed as the n-type chalcogenide compound 12 by the above method.

In some embodiments, the Ge₂(Sb₁₋ₓBiₓ)₂Te₅ may be formed by, for example, the co-sputtering process using Ge₂Sb₂Te₅ and Ge₂Bi₂Te₅ as the targets. The Ge₂Sb₂Te₅ and the Ge₂Bi₂Te₅ have the same elements except for Sb and Bi that are in the same group, or group 5B. If the Ge₂Sb₂Te₅ and the Ge₂Bi₂Te₅ are used as the targets, part of the Sb included in the Ge₂Sb₂Te₅ may be substituted with the Bi, and thus the Ge₂(Sb₁₋ₓBiₓ)₂Te₅ may be formed. By changing the ratio of the amount of Ge₂Bi₂Te₅ to the amount of Ge₂Sb₂Te₅ as the targets, the ratio of the Bi to the Sb may be adjusted in the Ge₂(Sb₁₋ₓBiₓ)₂Te₅. Thus, the n-type chalcogenide compound 14 that is thermally stable and has n-type conductivity may be formed by adjusting the amount of the Bi.

If the amount of the Ge₂Bi₂Te₅ is less than about 30 mol % in the n-type chalcogenide compound 14, the Ge₂(Sb₁₋ₓBiₓ)₂Te₅ may not have the n-type conductivity. If the amount of the Ge₂Bi₂Te₅ is more than about 60 mol % in the n-type chalcogenide compound 14, the Ge₂(Sb₁₋ₓBiₓ)₂Te₅ may be thermally unstable. Thus, it is preferable that the amount of the Ge₂Bi₂Te₅ is more than about 30 mol % and less than about 60 mol %. In some embodiments, the amount of the Ge₂Bi₂Te₅ is more than about 30 mol % and less than about 57 mol % so that the Ge₂(Sb₁₋ₓBiₓ)₂Te₅ may have the n-type conductivity and may be thermally stable.

In other examples, the n-type chalcogenide compound 14 may be formed, for example, by the sputtering process using Ge₂(Sb₁₋ₓBiₓ)₂Te₅ (0.3<x<0.6) as the target.

In still other examples, a p-type chalcogenide compound may be formed by, for example, the sputtering process using Ge₂(Sb₁₋ₓ)₂Te₅(0.3<x<0.6) as the target. The p-type chalcogenide compound is in an unstable state since the p-type chalcogenide compound lacks part of the Sb. The p-type chalcogenide compound is doped with the Bi, and the Bi is bonded to the compound lacking the Sb. Accordingly, the Ge₂(Sb₁₋ₓBiₓ)₂Te₅ (0.3<x<0.6) is formed.

In further still other example, the Ge₂(Sb₁₋ₓBiₓ)₂Te₅ (0.3<x<0.6) may be formed by, for example, the CVD process.

By the method described above, the photodiode 10 having a homojunction structure of the p-type chalcogenide compound 12 and the n-type chalcogenide compound 14 may be formed.

Hereinafter, the property of the Ge₂Sb₂Te₅ that is the p-type chalcogenide compound and the property of the Ge₂(Sb₁₋ₓBiₓ)₂Te₅ that is the n-type chalcogenide compound will be described below. The property change of the n-type chalcogenide compound according to the amount of the Bi will be described below. It will be verified whether the materials are suitable for the photodiode.

### Phase Separation Experiment

Ge₂Sb₂Te₅ is provided as the p-type chalcogenide compound, and Ge₂Bi₂Te₅ is provided as an n-type dopant. Ge₂(Sb₁₋ₓBiₓ)₂Te₅ is also provided as the n-type chalcogenide compound. The Ge₂(Sb₁₋ₓBiₓ)₂Te₅ is formed by the co-sputtering process, and the amount of Bi in the Ge₂(Sb₁₋ₓBiₓ)₂Te₅ varies by adjusting the amount of the Ge₂Bi₂Te₅ as a target according to samples of chalcogenide compounds. The samples of the chalcogenide compounds are described in table 1.

TABLE 1

| | | | | | | | Comparison |
|---|---|---|---|---|---|---|---|
| | Sample 1 | Sample 2 | Sample 3 | Sample 4 | Sample 5 | Sample 6 | Sample |
| Ge₂Sb₂Te₅ | 100 mol % | 86.9 mol % | 64.9 mol % | 61.6 mol % | 43.4 mol % | 38.8 mol % | |
| (Target 1) | | | | | | | |
| Ge₂Bi₂Te₅ | | 13.1 mol % | 35.1 mol % | 38.4 mol % | 56.6 mol % | 61.2 mol % | 100 mol % |
| (Target 2) | | | | | | | |

FIG. 2 is a graph illustrating X-ray diffraction patterns of Ge₂Sb₂Te₅, Ge₂(Sb₁₋ₓBiₓ)₂Te₅ and Ge₂Bi₂Te₅ at room temperature.

As illustrated in FIG. 2, Ge₂Sb₂Te₅ has an amorphous phase at room temperature of about 15° C. through about 25° C. Ge₂Bi₂Te₅ has periodic peaks, and thus the Ge₂Bi₂Te₅ has a crystalline phase. Ge₂(Sb₁₋ₓBiₓ)₂Te₅ has the amorphous phase or the crystalline phase according to the amount of the Ge₂Bi₂Te₅.

The Ge₂(Sb₁₋ₓBiₓ)₂Te₅ including the Ge₂Bi₂Te₅ of less than about 57 mol % has the amorphous phase as the Ge₂Sb₂Te₅ has. Accordingly, the phase separation may not occur between the Ge₂(Sb₁₋ₓBiₓ)₂Te₅ (x≦0.57) and the Ge₂Sb₂Te₅.

The phases of the samples found by the X-ray diffraction patterns are described in table 2.

TABLE 2

| | | | | | | | Comparison |
|---|---|---|---|---|---|---|---|
| | Sample 1 | Sample 2 | Sample 3 | Sample 4 | Sample 5 | Sample 6 | Sample |
| Phase | amorphous | amorphous | amorphous | amorphous | amorphous | crystalline | crystalline |

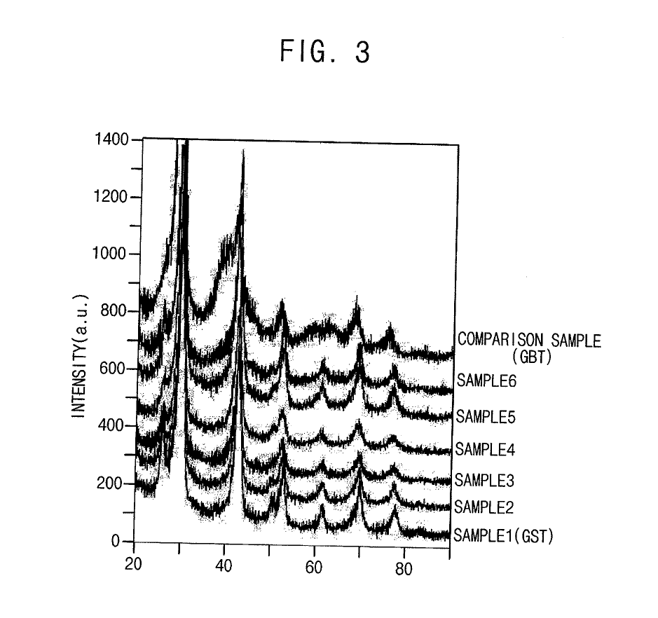

FIG. 3 a graph illustrating X-ray diffraction patterns of Ge₂Sb₂Te₅, Ge₂(Sb₁₋ₓBiₓ)₂Te₅and Ge₂Bi₂Te₅ heat-treated at about 200° C.

As illustrated in FIG. 3, Ge₂Sb₂Te₅, Ge₂(Sb₁₋ₓBiₓ)₂Te₅ and Ge₂Bi₂Te₅ have a crystalline phase of a face-centered cubic structure. Accordingly, the Ge₂(Sb₁₋ₓBiₓ)₂Te₅ may have a stable phase even at high temperature.

The phases of the heat-treated samples found by the X-ray diffraction patterns are described in table 3.

TABLE 3

| | | | | | | | Comparison |
|---|---|---|---|---|---|---|---|
| | Sample 1 | Sample 2 | Sample 3 | Sample 4 | Sample 5 | Sample 6 | Sample |
| Phase | crystalline | crystalline | crystalline | crystalline | crystalline | crystalline | crystalline |

After the heat treatment, the Ge₂(Sb₁₋ₓBiₓ)₂Te₅ that is the n-type chalcogenide compound has the same phase as the Ge₂Sb₂Te₅ that is the p-type chalcogenide compound.

Accordingly, a thermally stable photodiode may be obtained by combining the Ge₂Sb₂Te₅ that is the p-type chalcogenide compound and the Ge₂(Sb₁₋ₓBiₓ)₂Te₅ (x≦0.57) that is the n-type chalcogenide compound.

Experiment of Resistance Characteristic According to Temperature

Ge₂Sb₂Te₅ is provided as the p-type chalcogenide compound, and Ge₂Bi₂Te₅ is provided as an n-type dopant. Ge₂(Sb₁₋ₓBiₓ)₂Te₅ is also provided as the n-type chalcogenide compound. The Ge₂(Sb₁₋ₓBiₓ)₂Te₅ is formed by the co-sputtering process, and the amount of Bi in the Ge₂(Sb₁₋ₓBiₓ)₂Te₅ varies by adjusting the amount of the Ge₂Bi₂Te₅ as a target according to samples of chalcogenide compounds. The samples of the chalcogenide compounds in this experiment are the same as the samples in the phase separation experiment.

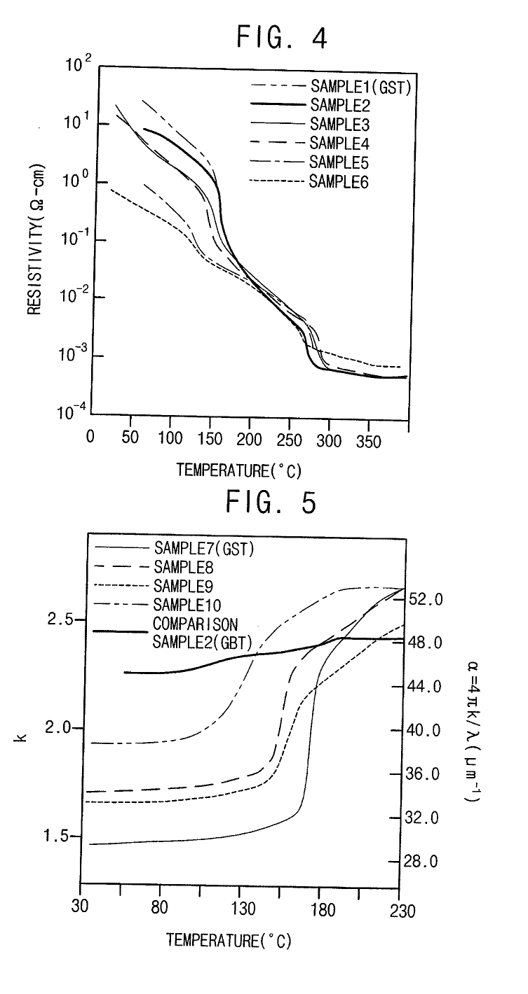

FIG. 4 a graph illustrating resistivity of Ge₂Sb₂Te₅, Ge₂(Sb₁₋ₓBiₓ)₂Te₅ and Ge₂Bi₂Te₅ according to temperature.

As illustrated in FIG. 4, Ge₂Bi₂Te₅ has a resistance lower than that of Ge₂Sb₂Te₅. A temperature, at which the resistance drastically decreases by the phase change, with respect to the Ge₂Bi₂Te₅ is lower than that of the Ge₂Sb₂Te₅.

As the amount of the Ge₂Bi₂Te₅ increases, Ge₂(Sb₁₋ₓBiₓ)₂Te₅ has a lower resistance compared to the Ge₂Sb₂Te₅, and has a lower temperature at which the resistance drastically decreases by the phase change.

The Ge₂Sb₂Te₅ and the Ge₂(Sb₁₋ₓBiₓ)₂Te₅ should have similar phase change characteristics according to temperature. Thus, it is preferable that the Ge₂(Sb₁₋ₓBiₓ)₂Te₅ includes the Ge₂Bi₂Te₅ of less than about 57 mol %.

The Ge₂(Sb₁₋ₓBiₓ)₂Te₅ including the Ge₂Bi₂Te₅ of less than about 57 mol % experiences a drastic resistance change at about 150° C. through about 170° C. and another drastic resistance change at about 260° C. through about 280° C. That is because the phase of the Ge₂(Sb₁₋ₓBiₓ)₂Te₅ changes from an amorphous phase to a face-centered cubic (FCC) phase at about 150° C. through about 170° C., and changes from the FCC phase to a hexagonal close packed (HCP) phase at about 260° C. through about 280° C. The phase change characteristic of the Ge₂Sb₂Te₅ is similar to that of the Ge₂(Sb₁₋ₓBiₓ)₂Te₅ (x≦0.57).

A chalcogenide compound experiences a drastic resistance change by the phase change. Thus, to be thermally stable, the p-type and n-type chalcogenide compounds used for the photodiode should have similar temperatures at which the phases change.

Since the Ge₂Sb₂Te₅ and the Ge₂(Sb₁₋ₓBiₓ)₂Te₅ (x≦0.57) have similar phase change characteristics, a thermally stable photodiode may be obtained by combining the Ge₂Sb₂Te₅ that is the p-type chalcogenide compound and the Ge₂(Sb₁₋ₓBiₓ)₂Te₅ (x≦0.57) that is the n-type chalcogenide compound.

### Experiment of Optical Characteristic According to Temperature

Ge₂Sb₂Te₅ is provided as the p-type chalcogenide compound, and Ge₂Bi₂Te₅ is provided as an n-type dopant. Ge₂(Sb₁₋ₓBiₓ)₂Te₅ is also provided as the n-type chalcogenide compound. The Ge₂(Sb₁₋ₓBiₓ)₂Te₅ is formed by the co-sputtering process, and the amount of Bi in the Ge₂(Sb₁₋ₓBiₓ)₂Te₅ varies by adjusting the amount of the Ge₂Bi₂Te₅ as a target according to samples of chalcogenide compounds. The samples of the chalcogenide compounds are described in table 4.

TABLE 4

| | | | | | Comparison |
|---|---|---|---|---|---|
| | Sample 7 | Sample 8 | Sample 9 | Sample 10 | Sample 2 |
| Ge₂Sb₂Te₅ | 100 mol % | 54 mol % | 42 mol % | 19 mol % | |
| (Target 1) | | | | | |
| Ge₂Bi₂Te₅ | | 46 mol % | 58 mol % | 81 mol % | 100 mol % |
| (Target 2) | | | | | |

FIG. 5 a graph illustrating extinction coefficients k and absorption coefficients α of Ge₂Sb₂Te₅, Ge₂(Sb₁₋ₓBiₓ)₂Te₅ and Ge₂Bi₂Te₅ according to temperature.

As illustrated in FIG. 5, an extinction coefficient k of Ge₂(Sb₁₋ₓBiₓ)₂Te₅ drastically changes at about 100° C. through about 160° C. since the phase of the Ge₂(Sb₁₋ₓBiₓ)₂Te₅ changes from an amorphous phase to an FCC phase.

As the amount of Ge₂Bi₂Te₅ increases, the extinction coefficient k of the Ge₂(Sb₁₋ₓBiₓ)₂Te₅ increases, and the temperature at which the phase of the Ge₂(Sb₁₋ₓBiₓ)₂Te₅ changes decreases.

The Ge₂(Sb₁₋ₓBiₓ)₂Te₅ having a thickness of about 100 nm has an absorption coefficient α of about 28 μm⁻¹ through about 60 μm⁻¹. Compared to silicon or group III-V compound semiconductor material, which has an absorption coefficient of about 20 μm⁻¹ at a thickness of about 3,000 nm, the Ge₂(Sb₁₋ₓBiₓ)₂Te₅ has the high absorption coefficient α.

Accordingly, since Ge₂Sb₂Te₅ that is the p-type chalcogenide compound and the Ge₂(Sb₁₋ₓBiₓ)₂Te₅ that is the n-type chalcogenide compound have high absorption coefficients α, a photodiode having high quantum efficiency and a low thickness may be obtained by combining the Ge₂Sb₂Te₅ and the Ge₂(Sb₁₋ₓBiₓ)₂Te₅.

### Conductivity Experiment

To verify conductivity of the p-type and the n-type chalcogenide compounds, field-effect transistor (FET) devices including the p-type and the n-type chalcogenide compounds as channels are formed. I-V characteristics of the FET devices will be described below.

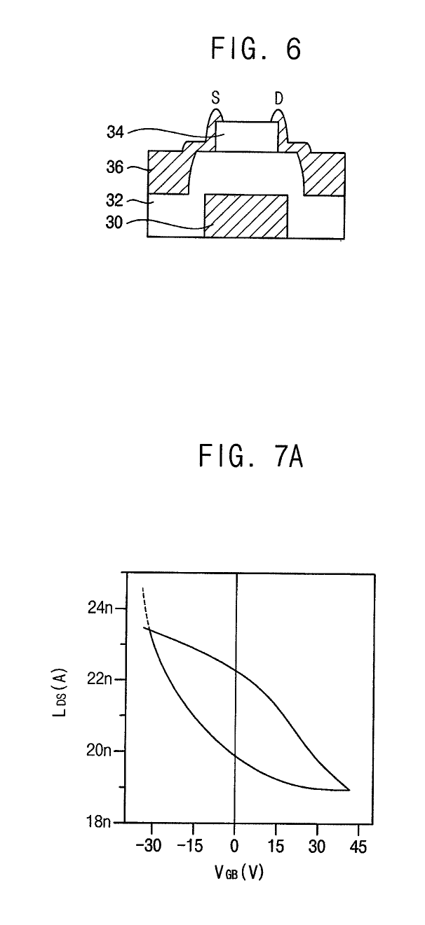

FIG. 6 is a cross-sectional view of a field-effect transistor (FET) device for conductive experiments.

Referring to FIG. 6, a gate electrode 30 including molybdenum (Mo) is formed on a substrate (not shown). A dielectric layer 32 is formed to cover the gate electrode 30. The dielectric layer 32 may be formed of, for example, silicon nitride. A channel pattern 34 including a chalcogenide compound is formed corresponding to the gate electrode 30 on the dielectric layer 32.

Compositions of the chalcogenide compounds included in the channel pattern 34 are different from each other according to samples of FET devices. A channel pattern of one FET sample is formed of Ge₂Sb₂Te₅. Channel patterns of the other FET samples are formed of Ge₂(Sb₁₋ₓBiₓ)₂Te₅. The Ge₂(Sb₁₋ₓBiₓ)₂Te₅ is formed by the co-sputtering process, and the amount of Bi in the Ge₂(Sb₁₋ₓBiₓ)₂Te₅ varies by adjusting the amount of Ge₂Bi₂Te₅ as a target according to the samples of the FET devices.

Source/drain electrodes 36 are formed at both ends of the channel pattern 34. The source/drain electrodes 36 may be formed of, for example, (Mo).

The samples of the FET devices are described in table 5.

TABLE 5

| | Sample 11 | Sample 12 | Sample 13 | Sample 14 | Sample 15 | Sample 16 |
|---|---|---|---|---|---|---|
| Ge₂Sb₂Te₅ | 100 mol % | 86.9 mol % | 77.0 mol % | 64.9 mol % | 61.6 mol % | 43.4 mol % |
| (Target 1) | | | | | | |
| Ge₂Bi₂Te₅ | | 13.1 mol % | 23.0 mol % | 35.1 mol % | 38.4 mol % | 56.6 mol % |
| (Target 2) | | | | | | |

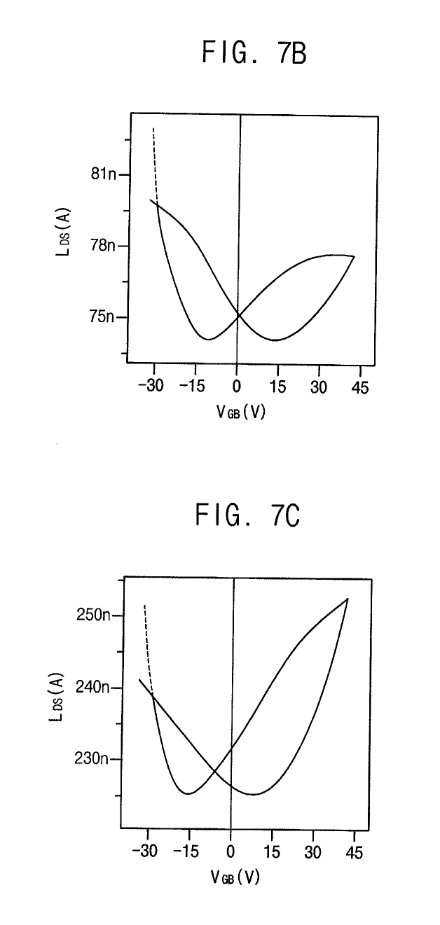

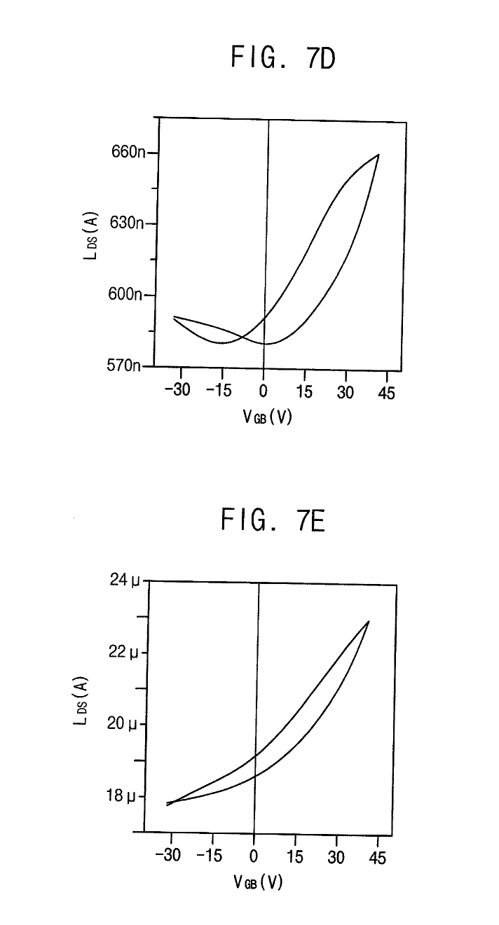

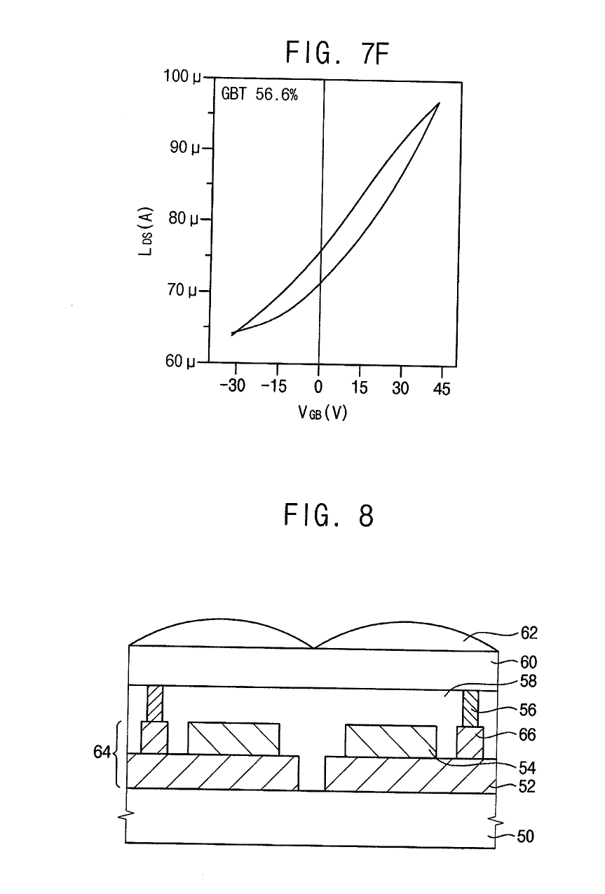

FIGS. 7A through 7F illustrate I-V curves of samples 1a through 6a, respectively.

Referring to FIG. 7A, sample 11 has an I-V curve of a typical p-type FET device. That is, it is verified that the Ge₂Sb₂Te₅ has p-type conductivity.

Referring to FIGS. 7B and 7C, samples 12 and 13 has bipolar conductivity. Since the channel pattern of samples 12 and 13 includes the Ge₂Bi₂Te₅ of less than about 30 mol %, it is verified that the Ge₂(Sb₁₋ₓBiₓ)₂Te₅ (x<0.3) has the bipolar conductivity.

Referring to FIGS. 7D through 7E, samples 14 through 16 have I-V curves of an n-type FET device. As the amount of the Ge₂Bi₂Te₅ included in the channel patter increases, the Ge₂(Sb₁₋ₓBiₓ)₂Te₅ has more n-type conductivity. If the amount of the Ge₂Bi₂Te₅ is more than about 30 mol %, the Ge₂(Sb₁₋ₓBiₓ)₂Te₅ has the n-type conductivity. Doping levels may be adjusted by the amount of the Ge₂Bi₂Te₅.

Accordingly, a photodiode having high quantum efficiency and a low thickness may be obtained by using the Ge₂(Sb₁₋ₓBiₓ)₂Te₅ (0.3<x<1) including the Ge₂Bi₂Te₅ of more than about 30 mol %.

The photodiode including the chalcogenide compounds according to example embodiments may be widely used in various optical devices. For example, the photodiode according to example embodiments may be applied to devices that use long wavelength light, such as infrared light, as well as visible light and require a high-performance photodiode having high quantum efficiency. For example, the photodiode according to example embodiments may be applied to image sensors, solar cells, photo detectors, etc.

Hereinafter, an infrared image sensor including a photodiode of FIG. 1 will be described below.

FIG. 8 is a cross-sectional view of an infrared image sensor according to example embodiments.

Referring to FIG. 8, an infrared image sensor is formed on a substrate 50 including an active pixel region and a logic region (not shown). Depth pixel sensors may be formed on the active pixel region of the substrate 50, and logic circuits (not shown) may be formed on the logic region of the substrate 50.

The depth pixel sensors formed on the active pixel region convert incident near-infrared light into an electrical signal. The near-infrared light may have a wavelength ranging from about 800 nm to about 900 nm. In some embodiments, the depth pixel sensors may use near-infrared light having a wavelength ranging from about 830 nm to about 870 nm as a light source.

Each depth pixel sensor may include a photodiode 64 that generates photo-charges in response to the near-infrared light, and transistors (not shown) that transfer the photo-charges generated in the photodiode 64 and amplify a signal corresponding to the photo-charges.

Conductive lines may be formed to electrically connect the transistors, and first and second dielectric layers 58 and 60 covering the transistors may be formed. A microlens 62 may be formed on the second dielectric layer 60. The microlens 62 may concentrate the incident near-infrared light on the photodiode 64.

The photodiode 64 is formed of chalcogenide compounds.

A p-type chalcogenide pattern 52 including a p-type chalcogenide compound is formed on the substrate 50. The p-type chalcogenide pattern 52 may be formed of, for example, Ge₂Sb₂Te₅. An n-type chalcogenide pattern 54 including an n-type chalcogenide compound is formed on the p-type chalcogenide pattern 52. The n-type chalcogenide pattern 54 may be formed of, for example, Ge₂(Sb₁₋ₓBiₓ)₂Te₅, where x is more than 0 and less than 1, preferably more than about 0.3 and less than about 0.6. Thus, the photodiode 64 may have a homojunction structure of the p-type chalcogenide pattern 52 and the n-type chalcogenide pattern 54.

A p+-type chalcogenide pattern 66 may be formed on the p-type chalcogenide pattern 52, and may be spaced apart from the n-type chalcogenide pattern 54. On the p+-type chalcogenide pattern 66, a contact 56 may be formed to transfer a ground signal to the p-type chalcogenide pattern 52.

In some embodiments, a near-infrared (NIR) band pass filter (not shown) may be formed on the second dielectric layer 60. The NIR band pass filter may selectively transmit light having a wavelength ranging, for example, from about 750 nm to about 870 nm. The NIR band pass filter may be formed along with the depth pixel sensor, or may be formed as an independent device. An image sensor that uses visible light may not include the NIR band pass filter.

As described above, the infrared image sensor according to example embodiments include the photodiode 64 formed of the chalcogenide compounds. Accordingly, the infrared image sensor may use the near-infrared light and may have high photo-electric conversion efficiency.

Hereinafter, a method of manufacturing the infrared image sensor illustrated in FIG. 8 will be described.

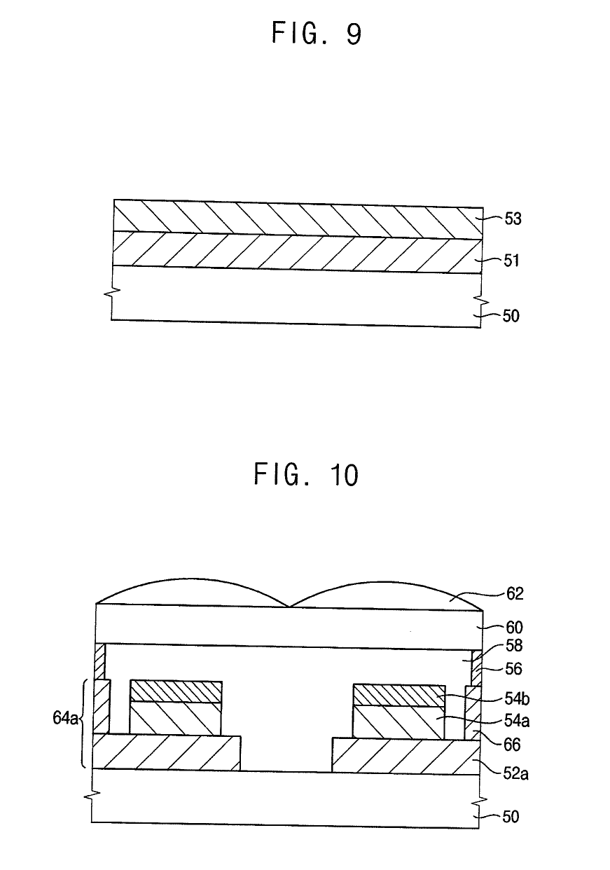

FIG. 9 is a cross-sectional view for describing a method of manufacturing an infrared image sensor of FIG. 8.

Referring to FIG. 9, a substrate 50 including an active pixel region and a logic region (not shown) is provided.

A p-type chalcogenide layer 51 and an n-type chalcogenide layer 53 are sequentially formed on the substrate 50. For example, the p-type chalcogenide layer 51 may be formed of Ge₂Sb₂Te₅, and the n-type chalcogenide layer 53 may be formed of Ge₂(Sb₁₋ₓBiₓ)₂Te₅, where x is more than 0 and less than 1, preferably more than about 0.3 and less than about 0.6. The layers 51 and 53 may be formed by the methods described above with reference to FIG. 1.

As illustrated in FIG. 8, an n-type chalcogenide pattern 54 is formed by patterning the n-type chalcogenide layer 53, and then a p-type chalcogenide pattern 52 is formed by patterning the p-type chalcogenide layer 51.

A p+-type chalcogenide pattern 66 is formed on the p-type chalcogenide pattern 52, and is spaced apart from the n-type chalcogenide pattern 54. In some embodiments, the p+-type chalcogenide pattern 66 may not be formed to simplify the process.

A first dielectric layer 58 is formed to cover the substrate 50 and the chalcogenide patterns 52, 54 and 66. A contact hole may be formed to expose an upper surface of the p+-type chalcogenide pattern 66 by etching a portion of the first dielectric layer 58. A contact 56 is formed by filling the contact hole with a conductive material.

A second dielectric layer 60 is formed on the first dielectric layer 58. A microlens 62 is formed on the second dielectric layer 60.

The infrared image sensor may be manufactured by the method described above.

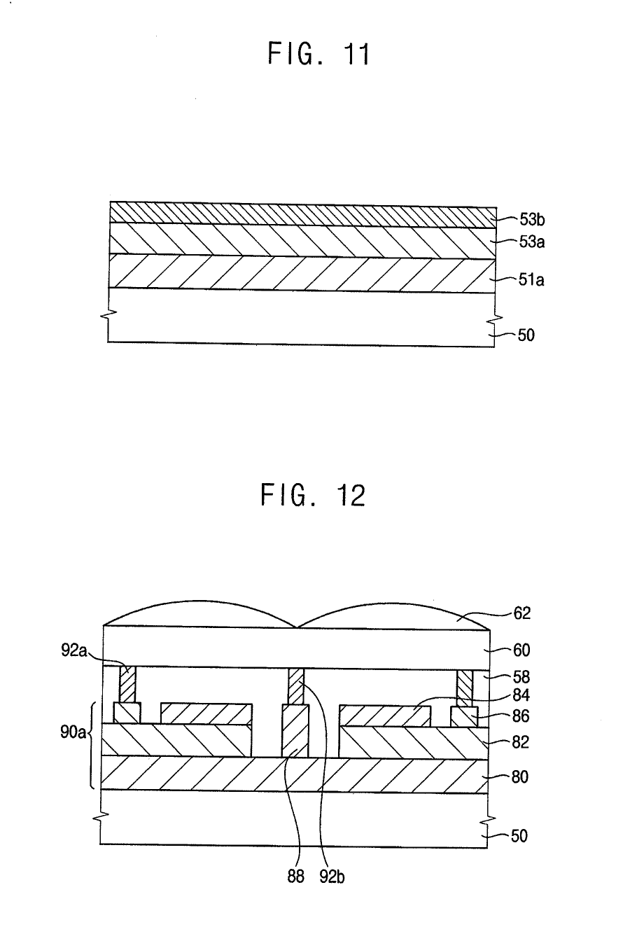

FIG. 10 is a cross-sectional view of an infrared image sensor according to example embodiments.

The infrared image sensor of FIG. 10 is similar to an infrared image sensor of FIG. 8 except for a structure of a photodiode 64a. The infrared image sensor of FIG. 10 may include a photodiode illustrated in FIG. 1.

Referring to FIG. 10, the photodiode 64a is formed on a substrate 50.

The photodiode 64a includes a p-type chalcogenide pattern 52a. The p-type chalcogenide pattern 52a may be formed of, for example, Ge₂Sb₂Te₅. An n−-type chalcogenide pattern 54a is formed on the p-type chalcogenide pattern 52a. An n+-type chalcogenide pattern 54b is formed on the n−-type chalcogenide pattern 54a. The n−-type chalcogenide pattern 54a and the n+-type chalcogenide pattern 54b may be formed of substantially the same materials. However, the concentration of an n-type dopant of the n+-type chalcogenide pattern 54b may be different from that of the n−-type chalcogenide pattern 54a. The n+-type chalcogenide pattern 54b may be spaced apart from the p-type chalcogenide pattern 52a.

The n−-type and n+-type chalcogenide patterns 54a and 54b may be formed of, for example, Ge₂(S₁₋ₓBiₓ)₂Te₅, where x is more than 0 and less than 1, preferably more than about 0.3 and less than about 0.6. As the amount of Bi that is the n-type dopant increases, the Ge₂(Sb₁₋ₓBiₓ)₂Te₅ has more n-type conductivity. The amount of the Bi included in the n−-type chalcogenide pattern 54a may be less than that of the n+-type chalcogenide pattern 54b. Electron-hole pairs may rapidly move by the n+-type chalcogenide pattern 54b, thereby reducing a signal transfer time

Thus, the photodiode 64a may have, for example, a homojunction structure of the p-type chalcogenide pattern 52a and the n−-type chalcogenide pattern 54a.

A p+-type chalcogenide pattern 66 may be formed on the p-type chalcogenide pattern 52a, and may be spaced apart from the n−-type chalcogenide pattern 54a. On the p+-type chalcogenide pattern 66, a contact 56 may be formed to transfer a ground signal to the p-type chalcogenide pattern 52.

Transistors (not shown) that transfer and amplify charges generated in the photodiode 64a, conductive lines and first and second dielectric layer 58 and 60 may be formed on the substrate 50. A microlens 62 may be formed on the second dielectric layer 60. The transistors, the conductive lines and the first and second dielectric layer 58 and 60 may be similar to those illustrated in FIG. 8.

Hereinafter, a method of manufacturing the infrared image sensor illustrated in FIG. 10 will be described.

FIG. 11 is a cross-sectional view for describing a method of manufacturing an infrared image sensor of FIG. 10.

Referring to FIG. 11, a substrate 50 including an active pixel region and a logic region (not shown) is provided. A p-type chalcogenide layer 51a, an n−-type chalcogenide layer 53a and an n+-type chalcogenide layer 53b are sequentially formed on the substrate 50. For example, the p-type chalcogenide layer 51a may be formed of Ge₂Sb₂Te₅, and the n−-type chalcogenide layer 53a and the n+-type chalcogenide layer 53b may be formed of Ge₂(Sb₁₋ₓBiₓ)₂Te₅, where x is more than 0 and less than 1, preferably more than about 0.3 and less than about 0.6. The amount of Bi included in the n−-type chalcogenide layer 53a may be less than that of the n+-type chalcogenide layer 53b.

As illustrated in FIG. 10, an n+-type chalcogenide pattern 54b and an n−-type chalcogenide pattern 54a are formed by sequentially patterning the n+-type chalcogenide layer 53b and the n−-type chalcogenide layer 53a, and then a p-type chalcogenide pattern 52a is formed by patterning the p-type chalcogenide layer 51a.

A p+-type chalcogenide pattern 66 may be formed on the p-type chalcogenide pattern 52a, and may be spaced apart from the n−-type chalcogenide pattern 54a.

Conductive lines, first and second dielectric layer 58 and 60 and a microlens 62 may be formed.

FIG. 12 is a cross-sectional view of an infrared image sensor according to example embodiments.

The infrared image sensor of FIG. 12 may include a photodiode illustrated in FIG. 1.

Referring to FIG. 12, a photodiode 90a is formed on a substrate 50.

The photodiode 90a includes a p-type chalcogenide layer 80. The p-type chalcogenide layer 80 may be formed of for example, Ge₂Sb₂Te₅.

An n−-type chalcogenide pattern 82 is formed on the p-type chalcogenide layer 80.

A first p+-type chalcogenide pattern 84 is formed on the n−-type chalcogenide pattern 82. The n−-type chalcogenide pattern 82 and the first p+-type chalcogenide pattern 84 may form a photodiode.

An n+-type chalcogenide pattern 86 is formed on the n−-type chalcogenide pattern 82, and is spaced apart from the first p+-type chalcogenide pattern 84. The n+-type chalcogenide pattern 86 may be coupled to conductive lines through a contact 92a. Charges may rapidly move by the n+-type chalcogenide pattern 86, thereby reducing a signal transfer time.

The p-type chalcogenide layer 80 and the first p+-type chalcogenide pattern 84 may be formed of the same materials, or may be formed of different materials.

The n−-type chalcogenide pattern 82 and the n+-type chalcogenide pattern 86 may be formed of substantially the same materials. However, the concentration of an n-type dopant of the n+-type chalcogenide pattern 86 may be different from that of the n−-type chalcogenide pattern 82. An upper surface of the n+-type chalcogenide pattern 86 may be located higher than that of the n−-type chalcogenide pattern 82. In some embodiments, the n+-type chalcogenide pattern 86 may be formed in the n−-type chalcogenide pattern 82, and the upper surface of the n+-type chalcogenide pattern 86 may be located at the same height as that of the n−-type chalcogenide pattern 82. The n+-type chalcogenide pattern 86 is disposed apart from the first p+-type chalcogenide pattern 84.

Thus, the photodiode 90a may have a homojunction structure of the n−-type chalcogenide pattern 82 and the first p+-type chalcogenide pattern 84. Vertical and horizontal charge transfers may be rapidly performed in the photodiode 90a.

A second p+-type chalcogenide pattern 88 may be formed on the p-type chalcogenide layer 88, and may be spaced apart from the chalcogenide patterns 82, 84 and 86. On the second p+-type chalcogenide pattern 88, a contact 92b may be formed to transfer a ground signal to the second p-type chalcogenide pattern 88.

A first dielectric layer 58 is formed on the substrate 50. The contacts 92a and 92b are formed through the first dielectric layer 58. A second dielectric layer 60 and a microlens 62 may be formed on the first dielectric layer 58.

Hereinafter, a method of manufacturing the infrared image sensor illustrated in FIG. 12 will be described.

FIG. 13 is a cross-sectional view for describing a method of manufacturing an infrared image sensor of FIG. 12.

Referring to FIG. 13, a substrate 50 including an active pixel region and a logic region (not shown) is provided. A p-type chalcogenide layer 80, an n−-type chalcogenide layer 83 and a first p+-type chalcogenide layer 85 are sequentially formed on the substrate 50.

As illustrated in FIG. 12, a first p+-type chalcogenide pattern 84 is formed by patterning the first p+-type chalcogenide layer 85, and then an n−-type chalcogenide pattern 82 is formed by patterning the n−-type chalcogenide layer 83.

A second p+-type chalcogenide pattern 88 may be formed on the p-type chalcogenide layer 80. In some embodiments, the second p+-type chalcogenide pattern 88 may not be formed to simplify the process.

First and second dielectric layer 58 and 60, conductive lines and a microlens 62 may be formed.

Hereinafter, a solar cell including a photodiode formed of chalcogenide compounds will be described below.

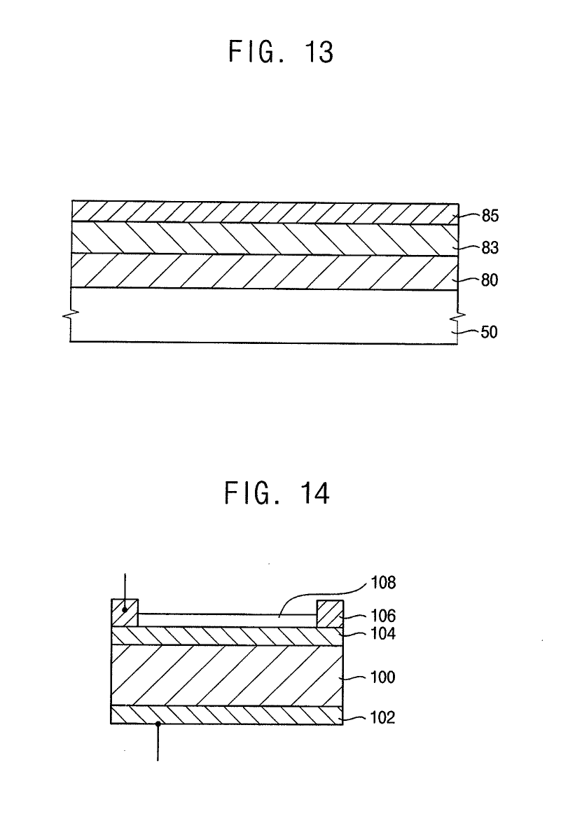

FIG. 14 is a cross-sectional view of a solar cell according to example embodiments.

The solar cell of FIG. 14 may include a photodiode illustrated in FIG. 1.

Referring to FIG. 14, a p-type chalcogenide thin film 100 is provided. The p-type chalcogenide thin film 100 may serve as a base. The p-type chalcogenide thin film 100 may be formed of, for example, Ge₂Sb₂Te₅. The p-type chalcogenide thin film 100 may have a thickness of less than, for example, about 10 μm.

A lower electrode 102 may be formed below a lower surface of the p-type chalcogenide thin film 100.

An n-type chalcogenide pattern 104 is formed on an upper surface of the p-type chalcogenide thin film 100. The n-type chalcogenide pattern 104 may serve as an emitter. The n-type chalcogenide pattern 104 may be formed of, for example, Ge₂(Sb₁₋ₓBiₓ)₂Te₅, where x is more than 0 and less than 1, preferably more than about 0.3 and less than about 0.6.

Thus, the solar cell according to some example embodiments includes a photodiode having a homojunction structure of the p-type chalcogenide thin film 100 and the n-type chalcogenide pattern 104.

An anti-reflection coating layer 108 is formed on the n-type chalcogenide pattern 104. The anti-reflection coating layer 108 may inhibit incident light from being reflected by the n-type chalcogenide pattern 104.

An upper electrode 106 is formed on the n-type chalcogenide pattern 104 through the anti-reflection coating layer 108. Most of an upper surface of the n-type chalcogenide pattern 104 may be covered by the anti-reflection coating layer 108 that the incident light enters, and a contact area between the upper electrode 106 and the n-type chalcogenide pattern 104 may be smaller than a contact area between the anti-reflection coating layer 108 and the n-type chalcogenide pattern 104.

The photodiode included in the solar cell according to some example embodiments may include chalcogenide compounds having a large photo-absorption coefficient and an energy bandgap lower than about 1.0 eV. Since the photodiode including the chalcogenide compounds may absorb infrared light as well as visible light, and thus the photodiode may have high photo-electric conversion efficiency. Further, the photodiode may be formed thin. For example, the photodiode may have a thickness of less than about 10 μm. Accordingly, charges may rapidly move without recombination, thereby reducing a signal transfer time.

A typical photodiode including a silicon material absorbs only visible light, and a conventional solar cell including the typical photodiode has low photo-electric conversion efficiency since the ratio of the visible light to the entire light of the sun is only about 29%. Further, to absorb long wavelength light, a silicon layer included in conventional solar cell should have a thickness of several tens or hundreds μm.

However, since the solar cell according to example embodiments includes the chalcogenide compounds instead of the silicon material, the solar cell according to example embodiments may be formed thin and may have high photo-electric conversion efficiency.

Hereinafter, a method of manufacturing a solar cell illustrated in FIG. 14 will be described below.

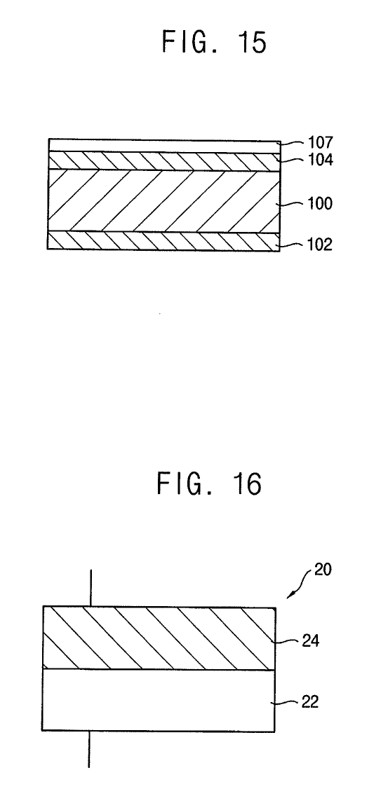

FIG. 15 is a cross-sectional view for describing a method of manufacturing a solar cell of FIG. 14.

Referring to FIG. 15, a p-type chalcogenide thin film 100 is provided. An n-type chalcogenide pattern 104 is formed on an upper surface of the p-type chalcogenide thin film 100. The n-type chalcogenide pattern 104 may be formed of, for example, Ge₂(Sb₁₋ₓBiₓ)₂Te₅, where x is more than 0 and less than 1, preferably more than about 0.3 and less than about 0.6. A lower electrode 102 may be formed below a lower surface of the p-type chalcogenide thin film 100. An anti-reflection coating material 107 is formed on the n-type chalcogenide pattern 104.

As illustrated in FIG. 14, an anti-reflection coating layer 108 is formed to include openings where an upper surface of the n-type chalcogenide pattern 104 is exposed by etching a portion of the anti-reflection coating material 107. An upper electrode 106 is formed by filling the openings with a conductive material.

Although it is not illustrated, conductive lines may be coupled to the upper electrode 106 and the lower electrode 102.

FIG. 16 is a cross-sectional view of a photodiode according to example embodiments.

Referring to FIG. 16, a photodiode 20 has a junction structure of a p-type semiconductor material 22 and an n-type chalcogenide compound 24. The p-type semiconductor material 22 may not include a chalcogenide compound.

The p-type semiconductor material 22 may include, for example, silicon or group III-V compound semiconductor material. Hereinafter, an example of the p-type semiconductor material 22 formed of silicon will be described below.

The n-type chalcogenide compound 24 may include, for example, Xₐ(Sb₁₋ₓBiₓ)_{b}S_{1-a-b}, Xₐ(Sb₁₋ₓBiₓ)_{b}Te_{1-a-b}, Xₐ(Sb₁₋ₓBiₓ)_{b}Se_{1-a-b} (0<a<1, 0<b<1, 0<x<1), etc. The X includes, for example, Si, Ge, Sn, Pb, Al, Ga, In, Cu, Zn, Ag, Cd, Ti, V, Cr, Mn, Fe, Co, Ni, or a combination thereof. Hereinafter, an example of the n-type chalcogenide compound 24 formed of Ge₂(Sb₁₋ₓBiₓ)₂Te₅ (0<x<1) will be described below. The n-type chalcogenide compound 24 may be obtained by substituting Bi for part of Sb included in the Ge—Sb—Te chalcogenide compound using Bi as a dopant.

As described above, the photodiode 20 may have a heterojunction structure of the p-type semiconductor material 22 and the n-type chalcogenide compound 24.

Hereinafter, a method of forming a photodiode illustrated in FIG. 16 will be described below.

A p-type silicon layer 22 is formed by doping a silicon material layer with a p-type dopant. The silicon material layer may be, for example, a silicon substrate.

An n-type chalcogenide compound 24 is formed on the p-type silicon layer 22.

The n-type chalcogenide compound 24 may be formed of, for example, Ge₂(Sb₁₋ₓBiₓ)₂Te₅. The Ge₂(Sb₁₋ₓBiₓ)₂Te₅ may be formed by the methods described above with reference to FIG. 1.

Accordingly, a photodiode 20 is formed to include the chalcogenide compound having a large photo-absorption coefficient and an energy bandgap lower than about 1.0 eV. The photodiode 20 according to example embodiment may have high photo-electric conversion efficiency.

In other embodiments, although it is not illustrated, a photodiode may have, for example, a heterojunction structure of a p-type chalcogenide compound and an n-type semiconductor material. According to example embodiments, at least one type of conductive materials in a photodiode may be a chalcogenide compound. Photoelectric devices according to example embodiments may include the photodiode.

Hereinafter, an infrared image sensor including a photodiode that includes a chalcogenide compound and has a heterojunction structure will be described below.

FIG. 17 is a cross-sectional view of an infrared image sensor including a photodiode of FIG. 16 according to example embodiments.

Referring to FIG. 17, an infrared image sensor is formed on a substrate 150 including an active pixel region and a logic region (not shown). The substrate 150 may be formed of, for example, single-crystalline silicon. Depth pixel sensors may be formed on the active pixel region of the substrate 150, and logic circuits (not shown) may be formed on the logic region of the substrate 150.

Each depth pixel sensor may include a photodiode 190 that generates photo-charges in response to the near-infrared light, and transistors (not shown) that transfer the photo-charges generated in the photodiode 190 and amplify a signal corresponding to the photo-charges. Conductive lines may be formed to electrically connect the transistors, and first and second dielectric layers 158 and 160 covering the transistors may be formed. A microlens 162 may be formed on the second dielectric layer 160.

The photodiode 190 has a junction structure of a p-type doped region 152 and an n-type chalcogenide pattern 154.

The p-type doped region 152 is formed in the substrate 150 by doping the substrate 150 with a p-type dopant. A device isolation pattern 150a is formed between the p-type doped regions 152 to electrically decouple the p-type doped regions 152 from each other. A p+-type doped region 166 is formed by heavily doping a portion of the p-type doped regions 152.

The n-type chalcogenide pattern 154 is formed on the p-type doped regions 152. The n-type chalcogenide pattern 154 may be formed of, for example, Ge₂(Sb₁₋ₓBiₓ)₂Te₅ (0<x<1). The n-type chalcogenide pattern 154 may be obtained by substituting Bi for part of Sb included in the Ge—Sb—Te chalcogenide compound using Bi as a dopant.

As described above, the infrared image sensor according to example embodiments includes the photodiode 190 having a heterojunction structure of the p-type doped region 152 and the n-type chalcogenide pattern 154. The photodiode 190 includes the chalcogenide compound having a large photo-absorption coefficient and an energy bandgap lower than about 1.0 eV. Accordingly, the infrared image sensor including the photodiode 190 may have high-performance.

The p+-type doped region 166 is spaced apart from the n-type chalcogenide pattern 154. A contact 156 may be formed on the p+-type doped region 166 to transfer a ground signal to the p-type doped region 152.

The infrared image sensor including the photodiode 190 may use near-infrared light.

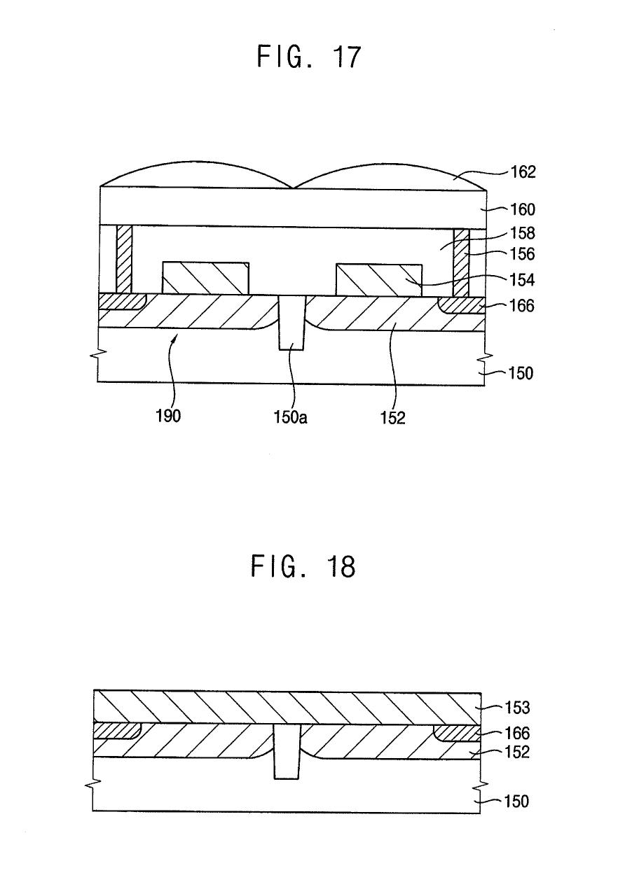

FIG. 18 is a cross-sectional view for describing a method of manufacturing an infrared image sensor of FIG. 17.

Referring to FIG. 18, a substrate 150 formed of single-crystalline silicon is provided. A trench device isolation pattern 150a is formed in the substrate 150 by a shallow trench isolation (STI) process. A p-type doped region 152 is formed by doping the substrate 150 with a p-type dopant. A p+-type doped region 166 as a pocket well is formed by heavily doping a portion of the p-type doped regions 152.

An n-type chalcogenide layer 153 is formed on the substrate 150 where the p-type doped region 152 is formed. The n-type chalcogenide layer 153 may be formed of, for example, Ge₂(Sb₁₋ₓBiₓ)₂Te₅ (0<x<1). The n-type chalcogenide layer 153 may be obtained by, for example, substituting Bi for part of Sb included in the Ge—Sb—Te chalcogenide compound using the Bi as a dopant.

As illustrated in FIG. 17, an n-type chalcogenide pattern 154 is formed by patterning the n-type chalcogenide layer 153. A first dielectric layer 158 is formed on the substrate 150 to cover the n-type chalcogenide pattern 154. A contact hole may be formed to expose an upper surface of the p+-type doped region 166 by etching a portion of the first dielectric layer 158. A contact 156 is formed by filling the contact hole with a conductive material. A second dielectric layer 160 and a microlens 162 are formed on the first dielectric layer 158.

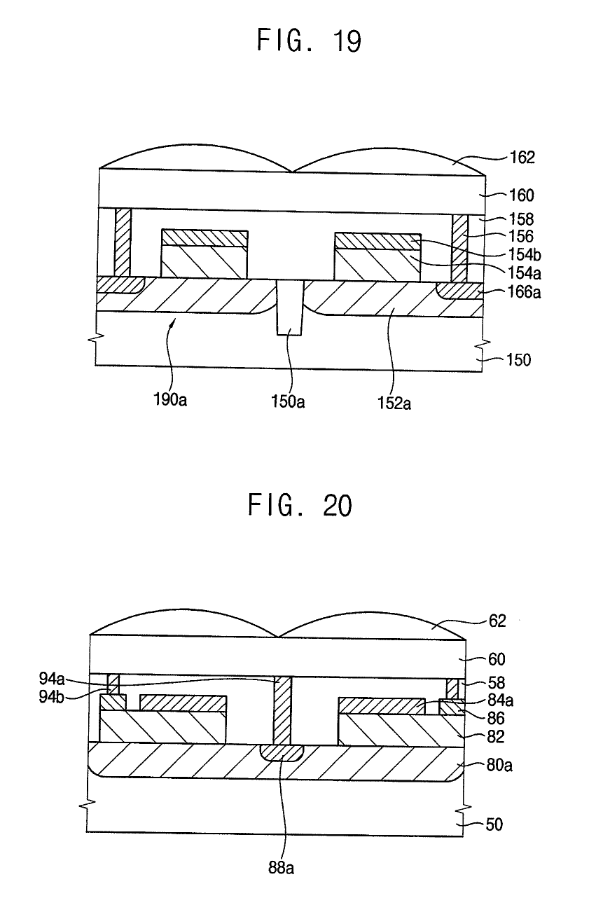

FIG. 19 is a cross-sectional view of an infrared image sensor according to example embodiments.

The infrared image sensor of FIG. 19 is similar to an infrared image sensor of FIG. 17 except for a structure of a photodiode.

Referring to FIG. 19, the photodiode 190a included in the infrared image sensor includes an n-type chalcogenide compound 154a and 154b.

The photodiode 190a has a junction structure of a p-type doped region 152a formed in a silicon substrate 150 and an n−-type chalcogenide pattern 154a. An n+-type chalcogenide pattern 154b is formed on the n−-type chalcogenide pattern 154a. The n−-type chalcogenide pattern 154a and the n+-type chalcogenide pattern 154b may be formed of substantially the same materials. However, the concentration of an n-type dopant of the n+-type chalcogenide pattern 154b may be different from that of the n−-type chalcogenide pattern 154a.

The n−-type and n+-type chalcogenide patterns 154a and 154b may be formed of, for example, Ge₂(Sb₁₋ₓBₓ)₂Te₅, where x is more than 0 and less than 1, preferably more than about 0.3 and less than about 0.6. As the amount of Bi increases, the Ge₂(Sb₁₋ₓBiₓ)₂Te₅ has more n-type conductivity. The amount of the Bi included in the n−-type chalcogenide pattern 154a may be less than that of the n+-type chalcogenide pattern 154b. Electron-hole pairs may rapidly move by the n+-type chalcogenide pattern 154b, thereby reducing a signal transfer time

Thus, the photodiode 190a may have a heterojunction structure of the p-type doped region 152a and the n−-type chalcogenide pattern 154a.

A p+-type doped region 166a as a pocket well is formed by heavily doping a portion of the p-type doped regions 152a, and is spaced apart from the n−-type chalcogenide pattern 154a.

A first dielectric layer 158 is formed on the substrate 150 to cover the n+-type chalcogenide patterns 154b. A contact 156 is formed on the p+-type doped region 166a to transfer a ground signal to the p-type doped region 152a. A second dielectric layer 160 and a microlens 162 are formed on the first dielectric layer 158.

Hereinafter, a method of manufacturing an infrared image sensor illustrated in FIG. 19 will be described below.

As the method described above with reference to FIG. 18, a trench device isolation pattern, a p-type doped region 152a and a p+-type doped region 166a are formed.

As illustrated in FIG. 19, an n−-type chalcogenide pattern 154a and an n+-type chalcogenide pattern 154b are formed by forming and patterning an n−-type chalcogenide layer and an n+-type chalcogenide layer.

A first dielectric layer 158 is formed on the substrate 150 to cover the n+-type chalcogenide patterns 154b. A contact 156 is formed on the p+-type doped region 166a through the first dielectric layer 158 to transfer a ground signal to the p-type doped region 152a. A second dielectric layer 160 and a microlens 162 are formed on the first dielectric layer 158.

FIG. 20 is a cross-sectional view of an infrared image sensor according to example embodiments.

Referring to FIG. 20, a p-type doped region 80a is formed in a substrate 50. An n−-type chalcogenide pattern 82 is formed on the p-type doped region 80a. A p-type semiconductor pattern 84a is formed on the n−-type chalcogenide pattern 82. The p-type semiconductor pattern 84a may include, for example, a silicon pattern or group III-V compound semiconductor pattern.

An n+-type chalcogenide pattern 86 is formed on the n−-type chalcogenide pattern 82, and is spaced apart from the p-type semiconductor pattern 84a. The n+-type chalcogenide pattern 86 may be coupled to conductive lines through a contact 94a. Charges may rapidly move by the n+-type chalcogenide pattern 86, thereby reducing a signal transfer time.

The n−-type chalcogenide pattern 82 and the n+-type chalcogenide pattern 86 may be formed of substantially the same materials. However, the concentration of an n-type dopant of the n+-type chalcogenide pattern 86 may be different from that of the n−-type chalcogenide pattern 82.

Thus, a photodiode may have, for example, a homojunction structure of the n−-type chalcogenide pattern 82 and the p-type semiconductor pattern 84a. Vertical and horizontal charge transfers may be rapidly performed in the photodiode.

A p+-type doped region 88a may be formed in the p-type doped region 80a. A contact 94a may be formed to transfer a ground signal to the p-type doped region 80a.

Hereinafter, a method of manufacturing the infrared image sensor illustrated in FIG. 20 will be described.

As illustrated in FIG. 20, a trench device isolation pattern (not shown) is formed in a substrate 50 of single-crystalline silicon by a shallow trench isolation (STI) process. A p-type doped region 80a and a p+-type doped region 88a as a pocket well are formed by doping the substrate 50 with a p-type dopant.

An n−-type chalcogenide layer (not shown) and a p-type semiconductor layer (not shown) are sequentially formed on the substrate 50. A p-type semiconductor pattern 84a is formed by pattering the p-type semiconductor layer, and then an n−-type chalcogenide pattern 82 is formed by pattering the n−-type chalcogenide layer.

An n+-type chalcogenide pattern 86 is formed on the n−-type chalcogenide pattern 82, and is spaced apart from the p-type semiconductor pattern 84a.

A first dielectric layer 58 is formed on the substrate 50. Contacts 94a and 94b are formed on the p+-type doped region 88a and the n+-type chalcogenide pattern 86 through the first dielectric layer 58. A second dielectric layer 60 and a microlens 62 may be formed on the first dielectric layer 58.

Hereinafter, a solar cell including the photodiode will be described below.

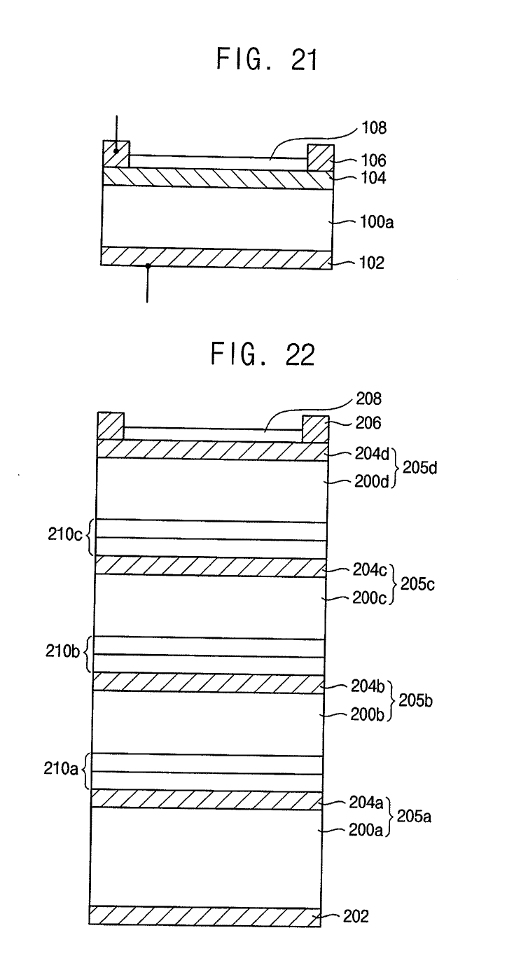

FIG. 21 is a cross-sectional view of a solar cell according to example embodiments.

Referring to FIG. 21, a p-type semiconductor thin film 100a is provided. The p-type semiconductor thin film 100a may serve as a base. The p-type semiconductor thin film 100a may not include a chalcogenide compound. The p-type semiconductor thin film 100a may be formed of, for example, silicon or group III-V compound semiconductor material.

A lower electrode 102 may be formed below a lower surface of the p-type semiconductor thin film 100a.

An n-type chalcogenide pattern 104 is formed on an upper surface of the p-type semiconductor thin film 100a. The n-type chalcogenide pattern 104 may serve as an emitter. The n-type chalcogenide pattern 104 may be formed of, for example, Ge₂(Sb₁₋ₓBiₓ)₂Te₅, where x is more than 0 and less than 1, preferably more than about 0.3 and less than about 0.6.

Thus, the solar cell according to some example embodiments includes a photodiode having a heterojunction structure of the p-type semiconductor thin film 100a and the n-type chalcogenide pattern 104.

An anti-reflection coating layer 108 is formed on the n-type chalcogenide pattern 104. An upper electrode 106 is formed on the n-type chalcogenide pattern 104 through the anti-reflection coating layer 108.

The photodiode including the chalcogenide compounds may absorb infrared light as well as visible light, and thus the photodiode may have high photo-electric conversion efficiency.

A method of manufacturing the solar cell of FIG. 21 may be similar to the method described above with reference to FIG. 14 except that the thin film 100a is formed of silicon.

FIG. 22 is a cross-sectional view of a solar cell according to example embodiments.

FIG. 22 illustrates a monolithic multiple junction solar cell, which includes a plurality of solar cells to absorb most of energy from the sun spectrum. At least one of the solar cells includes a chalcogenide compound. For example, the solar cells may include chalcogenide compounds of which energy bandgaps are different from each other.

Referring to FIG. 22, a monolithic four junction solar cell is provided. In the monolithic four junction solar cell, first thorough fourth solar cells 205a, 205b, 205c and 205d may have energy bandgaps of about 0.67 eV, about 1.05 eV, about 1.42 eV and about 1.9 eV, respectively, to absorb most of energy from the sun spectrum. The first and the second solar cells 205a and 205b may include a chalcogenide material to have the energy bandgaps of about 0.67 eV and about 1.05 eV, respectively. The third and the fourth solar cells 205c and 205d may include, for example, a group III-V compound semiconductor material to have the energy bandgaps of about 1.42 eV and about 1.9 eV, respectively. For example, the third solar cell 205c may include GaAs, and the fourth solar cell 205d may include InGaP.

Tunnel junction layers 210a, 210b and 210c may be formed between the solar cells 205a, 205b, 205c and 205d. An upper electrode 206 and a lower electrode 202 are formed. An anti-reflection coating layer 208 is formed on the fourth solar cell 205d.

If light of the sun enters the monolithic solar cell, the first through fourth solar cells 205a, 205b, 205c and 205d may absorb respective portions of the light, which are different from each other in wavelength.

Since the first through fourth solar cells 205a, 205b, 205c and 205d absorb the light of different wavelengths, respectively, the monolithic solar cell may have high photo-electric conversion efficiency. For example, by using the chalcogenide material having an energy bandgap lower than about 1.1 eV, the monolithic solar cell may be thermally stable and may have high photo-electric conversion efficiency.

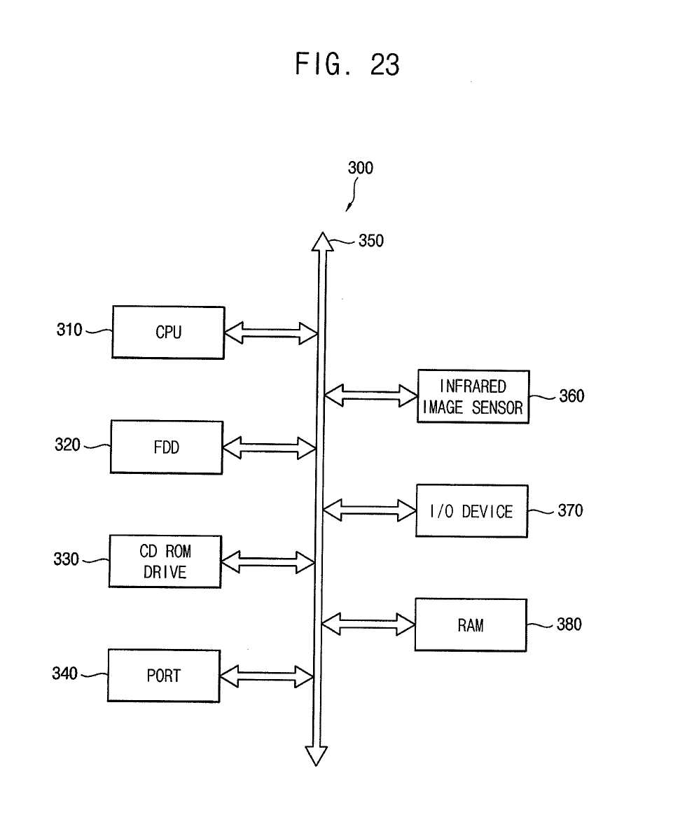

FIG. 23 is a block diagram illustrating a computing system according to example embodiments.

Referring to FIG. 23, a system 300 includes an infrared image sensor 360. For example, the system 300 may include a computing system, a camera system, a scanner, a navigation system, etc.

For example, the processor-based system 300, such as the computing system, includes a central processing unit (CPU) 310, such as a microprocessor, that communicates with an input/output device 370 via a bus 350. For example, a floppy disc drive 320, a CD-ROM drive 330, a port 340, a RAM 380 and the CPU 310 may communicate with each other via the bus 350, and may receive and process depth data from the infrared image sensor 360. The port 340 may be coupled to, for example, a video card, a sound card, a memory card, an USB device, etc., or may be coupled to another system.

Although it is not illustrated, the photodiode including a chalcogenide compound according to example embodiments may be applied to various photo receiving devices. For example, the photodiode according to example embodiments may be applied to a photo-electronic device, such as an optical communication equipment, a photo-coupler, a video disc, an audio disc, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A photodiode, comprising:
a p-type semiconductor material; and
an n-type chalcogenide compound forming a pn-junction with the p-type semiconductor material.

2. The photodiode of claim 1, wherein the p-type semiconductor material is a p-type chalcogenide compound, and wherein the pn-junction is a homojunction.

3. The photodiode of claim 2, wherein the p-type semiconductor material is selected from the group consisting of XₐSb_{b}S_{1-a-b}, XₐSb_{b}Te_{1-a-b} and XₐSb_{b}Se_{1-a-b}, where 0<a<1, 0<b<1, and X is selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni) or a combination thereof.

4. The photodiode of claim 2, wherein the p-type semiconductor material is Ge₂Sb₂Te₅.

5. The photodiode of claim 1, wherein the p-type semiconductor material is a silicon material or a group III-V compound semiconductor material, and wherein the pn-junction is a heterojunction.

6. The photodiode of claim 1, wherein the n-type chalcogenide compound is obtained from a p-type chalcogenide compound by substituting bismuth (Bi) for at least part of an element included in the p-type chalcogenide compound.

7. The photodiode of claim 1, wherein the n-type chalcogenide compound is selected from the group consisting of Xₐ(Sb₁₋ₓBₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b}, where 0<a<1, 0<b<1, 0<x<1, and X is selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni) or a combination thereof.

8. The photodiode of claim 7, wherein x in Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b} is more than about 0.3 and less than about 0.6.

9. The photodiode of claim 1, wherein the n-type chalcogenide compound is Ge₂(Sb₁₋ₓBiₓ)₂Te₅, where 0<x<1.

10. The photodiode of claim 1, wherein the n-type chalcogenide compound is formed by a co-sputtering process using a first target including bismuth (Bi) and a second target including no Bi.

11. The photodiode of claim 10, wherein the first target is Ge₂Bi₂Te₅, and the second target is Ge₂Sb₂Te₅.

12. The photodiode of claim 11, wherein an amount of Ge₂Bi₂Te₅ in the n-type chalcogenide compound is more than about 30 mol % and less than about 60 mol %.

13. A photodiode, comprising:
a p-type semiconductor material; and
an n-type chalcogenide compound formed on an upper surface of the p-type semiconductor material to form a pn-junction structure with the p-type semiconductor material, wherein the p-type semiconductor material is a silicon material or a group III-V compound semiconductor material, wherein the n-type chalcogenide compound is selected from the group consisting of Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b}, where 0<a<1, 0<b<1, 0<x<1, and X is selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni) or a combination thereof and wherein x in Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b} is more than about 0.3 and less than about 0.6.

14. The photodiode of claim 13, wherein the p-type semiconductor material is formed of silicon and the n-type chalcogenide compound is Ge₂(Sb₁₋ₓBiₓ)₂Te₅.

15. A photodiode, comprising:
a p-type chalcogenide compound; and
an n-type chalcogenide compound formed on an upper surface of the p-type chalcogenide compound to form a pn-junction structure with the p-type chalcogenide compound, wherein the p-type chalcogenide compound is selected from the group consisting of XₐSb_{b}S_{1-a-b}, XₐSb_{b}Te_{1-a-b} and XₐSb_{b}Se_{1-a-b}, where 0<a<1, 0<b<1, and X is selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni) or a combination thereof, wherein the n-type chalcogenide compound is selected from the group consisting of Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b}, where 0<a<1, 0<b<1, 0<x<1, and X is selected from the group consisting of Si, Ge, Sn, Pb, Al, Ga, In, Cu, Zn, Ag, Cd, Ti, V, Cr, Mn, Fe, Co and Ni or a combination thereof and wherein x in Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b} is more than about 0.3 and less than about 0.6.

16. The photodiode of claim 15, wherein the p-type chalcogenide compound is Ge₂Sb₂Te₅ and the n-type chalcogenide compound is Ge₂(Sb₁₋ₓBiₓ)₂Te₅.

17. An image sensor, comprising:
a photodiode according to claim 1;
a transfer device configured to transfer photo-charges generated in the photodiode; and
a dielectric layer covering the transfer device.

18. The image sensor of claim 17, wherein the n-type chalcogenide compound is selected from the group consisting of Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}Se_{1-a-b}, where 0<a<1, 0<b<1, 0<x<1, and X is selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni) or a combination thereof.

19. A solar cell, comprising:
a photodiode according to claim 1;
a lower electrode formed on a surface of the p-type semiconductor material; and
an upper electrode formed on a portion of a surface of the n-type chalcogenide compound.

20. The solar cell of claim 19, wherein the n-type chalcogenide compound is selected from the group consisting of Xₐ(Sb₁₋ₓBiₓ)_{b}S_{1-a-b}, Xₐ(Sb₁₋ₓBiₓ)_{b}Te_{1-a-b} and Xₐ(Sb₁₋ₓBiₓ)_{b}S_{1-a-b}, where 0<a<1, 0<b<1, 0<x<1, and X is selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni) or a combination thereof.
